(19) United States
(12) Patent Application Publication
(10) Pub. No.: US 2016/0024678 A1
(43) Pub. Date: Jan. 28, 2016

(54) PREFERRED ORIENTED AU FILM, METHOD FOR PREPARING THE SAME AND BONDING STRUCTURE COMPRISING THE SAME

(71) Applicant: National Chiao Tung University, Hsinchu City (TW)

(72) Inventors: Chih CHEN, Hsinchu City (TW); Wei-Lan CHIU, Hsinchu City (TW)

(21) Appl. No.: 14/664,316

(22) Filed: Mar. 20, 2015

(30) Foreign Application Priority Data
Jul. 24, 2014 (TW) 103125237

(51) Int. Cl. C25D 5/18; C22C 5/02; C25D 7/12; H01L 23/00; B32B 15/01

(52) U.S. Cl. CPC C25D 5/18; H01L 24/32; B32B 15/01; C25D 7/12; C22C 5/02; H01L 2224/32501; H01L 2924/01079

(57) ABSTRACT

The present invention relates to a preferred oriented Au film, a method for preparing the same, and a bonding structure comprising the same. The Au film comprises a plurality of Au grains connected to each other, wherein at least 50% by volume of the Au grains are composed of a plurality of nano-twin Au grains, and the nano-twin Au grains are formed of a plurality of nano-twin Au stacked along a [111] crystal axial orientation.

### CROSS REFERENCE TO RELATED APPLICATION

This application claims the benefits of the Taiwan Patent Application Serial Number 103125237, filed on Jul. 24, 2014, the subject matter of which is incorporated herein by reference.

### BACKGROUND OF THE INVENTION

1. Field of the Invention

The present invention relates to a preferred oriented Au film, a method for preparing the same, and a bonding structure comprising the same, and especially to an Au film comprising a plurality of preferred [111] oriented nanotwinned Au grains, a method for preparing the same, and a bonding structure comprising the same.

2. Description of Related Art

The hardness and mechanical properties of a metal material may be varied with the grain size. For example, a number of nano-grains and metal films with a nanotwinned structure have a particularly high hardness. Such a high hardness can be applied to the surfaces of the accessories or jewelry-inlaying metals to improve their hardness and wear resistance, and ensure the inlaid precious stone does not fall off. In addition, the nanotwinned metal with nano-crystallinity can also be applied as the metal materials of a through silicon via (TSV), an interconnect, a pin through hole, a metal wire (e.g., a copper interconnect), a circuit of a substrate or so on, to ensure the reliability of the electrical contacts, and prolong the service life.

In terms of electricity, the crystal structures may affect the electromigration resistance which may be improved by changing the lattice structure of the wire to render the internal grain structure of the wire with the preferred [111] orientation, thus significantly increasing the electromigration resistance. Alternatively, formation of the nanotwinned metal structure can slow down the atom loss rate at the boundaries between the nanotwinned grains when the atoms migrate along the direction of electron flow. Thus, the formation rate of voids can slow down, thus improving the operation lifetime of the electronic components.

In addition, since the development of electronic products today majorly tend to be lighter and thinner, and the response and operation speed of the electronic products also adopt more stringently requirement. The packages of the semiconductor chips are developed from one-dimensional and 2-dimensional to 2.5-dimensional or 3-dimensional structures. Because the semiconductor chips are vertically stacked in the 2.5-dimensional and 3-dimensional package, the routing design for signal transduction is crucial for successful operation of the semiconductor chips which are stacked in high density. The metal bonding structure for electrical connection needs to comply with narrow spacing and high bonding reliability, as well as excellent mechanical strength and good conductivity. As such, the materials and the manufacturing process do play an important role.

Gold is a highly suitable metal for electrical connection in the package structure due to its high conductivity nature. However, in the conventional Au contacts, the Au grains have no specific crystallographic orientation, and instead, grains with random orientations are formed at the surface of the contact. Thus the bonding process should be performed at a high temperature or high pressure, which is likely to damage the semiconductor chip. If the temperature of the gold bonding process is decreased, a higher pressure is required. In this way, the gold bonding process would be too complicated and necessitate expensive equipment, and the overly high pressure could damage the components easily, thus making mass product difficult.

Therefore, what is needed in the art is a novel Au film and a method for preparing the same, which has a preferred orientation and a nanotwinned structure, and a novel Au bonding structure and a method for preparing the same, which not only can be used in the jewelry industry, but can also be applied in the electronics industry, to improve the shortcomings of conventional high-temperature and high-pressure process, thereby enhancing the product yield, reducing the costs, and achieving high-performance, compact electronic products.

### SUMMARY OF THE INVENTION

The present invention provides a preferred oriented Au film and a method for preparing the same, and the Au film comprises a plurality of nanotwinned Au grains, so as to render the Au film with good hardness and mechanical properties. The Au film can be used in jewelry industry and the gold ornament industry, wherein an Au film comprising a plurality of nanotwinned Au grains can be formed on the surface of the gold ornament to increase its hardness without affecting its appearance.

Furthermore, the preferably oriented Au film of the present invention has excellent mechanical properties and cicetronligration resistance ability. The present invention also provides a bonding structure having a preferably oriented Au film and a preparation method thereof, to be applied to the electrical contacts in a variety of electronic products, wherein the growth directions of the Au grains are controlled to form the preferred oriented [111] crystal plane on the Au film surface. As shown in FIG. 1, the gold atoms are stacked along the [111] orientation to form a [111] crystal plane 111. The bonding structure having the preferred oriented Au film of the present invention combines two advantageous characteristics: (1) the [111] crystal plane of Au has a maximum plane bulk density, and (2) Au grains have the highest self-diffusion rate in the [111] orientation. Accordingly, the Au film having the [111] crystal plane may achieve good bonding at low temperature and low pressure.

The preferred oriented Au film of the present invention comprises a plurality of Au grains connected to each other, wherein at least 50% by volume of the Au grains are composed of a plurality of nanotwinned Au grains, and the nano-twin Au grains are formed of a plurality of nanotwinned Au stacked along a [111] crystal axial orientation. In addition, the Au film has a thickness direction, and any cross-section perpendicular to the thickness direction has at least 50% by area of a [111] crystal plane.

The preferred oriented Au film of the present invention may have a thickness of 0.05-1000 μm, and preferably 1-10 wherein the nanotwinned Au grains may have a thickness of 0.05-1000 μm, preferably 1-10 μm, and a diameter of 0.1-10 μm, preferably 0.5-5 μm.

Another object of the present invention is to provide a method for preparing a preferred oriented Au film, comprising: (A) providing a plating apparatus comprising an anode, a cathode, a pulsed current supply, and a plating solution, wherein the pulse current supply is electrically connected to the anode and the cathode which are immersed in the plating solution; and (B) providing a pulse current for plating by using the pulsed current supply to grow an Au film on a surface of the cathode; wherein the Au film comprises a plurality of Au grains connected to each other, wherein at least 50%, and preferably at least 75% by volume of the Au grains are composed of a plurality of nanotwinned Au grains, and the nanotwinned Au grains are formed of a plurality of nanotwinned Au stacked along a [111] crystal axial orientation. In addition, the plating solution may include a gold ion, a chloride ion, and an acid.

According to the method for preparing a preferred oriented Au film of the present invention, in the step (B), the cathode or the plating solution is rotated at a rotational speed of 500-2000 rpm when plating, and preferably 800-1600 rpm, in order to improve the growth orientation and speed of the nanotwinned grains.

According to the method for preparing a preferred oriented Au film of the present invention, in the step (B), the pulse current supply may provide a pulse current having Tₒₙ/T_{off} (sec) of 0.1/1 to 0.1/2.0, and preferably 0.1/1 to 0.1/1.6. Furthermore, the pulse current supply may provide a pulse current having a current density of 1-100 mA/cm², and preferably 1-10 mA/cm ².

According to the method for preparing a preferred oriented Au film of the present invention, the plating solution may further comprise at least one selected from the group consisting of: a surfactant, a lattice modification agent, and mixtures thereof. The acid of the plating solution may be at least one selected from the group consisting of: hydrochloric acid, nitric acid, and sulfuric acid, and preferably hydrochloric acid and nitric acid. The acid of the plating solution may have a concentration of 5-15 g/L, and preferably 8-12 g/L. Furthermore, the gold ion of the plating solution is obtained by dissociation of a gold-containing salt which may be at least one selected from the group consisting of: a sulfate and a sulfite, and preferably a sulfite. The chloride ion mainly functions to fine-tune the grain growth direction, in order to render the nanotwinned metal with preferred crystal orientation. The chloride ion of the plating solution may be at least one selected from the group consisting of: hydrochloric acid (HCl), perchloric acid (HClO₄), chloric acid (HClO₃), chlorous acid (HClO₂), and hypochlorous acid (HOCl), and preferably hydrochloric acid (HCl) and chloric acid (HClO₃).

According to the method for preparing a preferred oriented Au film of the present invention, the thickness of the plating deposited Au film can be adjusted by the length of the plating time, and the preferred oriented Au film of the present invention may have a thickness of 0.05-1000 μm, and preferably 1-10 μm, wherein the nanotwinned Au grains may have a thickness of 0.05-100 μm, preferably 1-10 μm, and may have a diameter of 0.1-10μm, preferably 0.5-5 μm.

As shown in the schematic cross-sectional view of FIG. 3B and the perspective view of FIG. 3B of the focused ion beam (FIB), the preferred oriented Au film 30 of the present invention is made of a large number of the grains 31 including a plurality of a layered nanotwinned Au grains 311 (e.g., the nanotwinned structure composed of a pair of adjacent black line and white line), wherein the nanotwinned Au grains 312 are stacked sequentially on the [111] crystal plane, to form the preferred oriented nanotwinned Au grains 311.

Based on the above-described Au film, another object of the present invention to provide a bonding structure having the preferred oriented Au film, comprising: a first substrate having a first Au film; a second substrate having a second Au film; wherein the first Au film and the second Au film are connected to each other and have a bonding interface which has 50 to 100% by area of a [111] crystal plane.

In the bonding structure of the present invention, the first substrate and the second substrate may be independently selected from the group consisting of: a semiconductor chip, a circuit board, a conductive substrate, and various electronic components.

In the bonding structure of the present invention, the thickness of the first Au film and the second Au film may be designed according to the electrical connecting structures of the first substrate and the second substrate, and controlled by the regulation of the growth parameters. Their thicknesses may be each independently 0.05-1000 μm, and preferably 1-500 μm.

Furthermore, in the bonding structure of the present invention, the first Au film and the second Au film comprise a plurality of Au grains connected to each other, wherein at least 50% by volume of at least one of the first Au film and the second Au film are composed of a plurality of nanotwinned Au grains. In other words, at least one of the first Au film and the second Au film is the preferred oriented Au film of the present invention.

The bonding structure having the preferred oriented Au film of the present invention can be used to electrically connect the first substrate and a second substrate, and its preparation method may comprise: (A) providing a first substrate and a second substrate; (B) forming a first metal film on the first substrate which has an exposed first Au film surface; as well as forming a second metal film on the second substrate which has an exposed second Au film surface, wherein the first Au film surface of the first Au film has 50 to 100% by area of the [111] crystal plane, while the second Au film surface of the second Au film has 0 to 100% by area of the [111] crystal plane; (C) performing a bonding process, such that the first Au film surface and the second Au film surface are contacted with each other, and applying a pressing force, such that the first metal film and the second metal film are bonded to each other to form an Au bonding interface, wherein the pressing force is 1 MPa or less; wherein the bonding interface has 50 to 100% by area of a [111] crystal plane.

According to the method for preparing the bonding structure of the present invention, in the step (A), each of the first substrate and the second substrate is independently selected from the group consisting of: a semiconductor chip, a circuit board, a conductive substrate, and a variety of electronic components.

In addition, according to the method for preparing the bonding structure of the present invention, in the step (B), the method for forming the first Au film and the second Au film is not particularly limited, and may be each independently selected from the group consisting of an electron gun evaporation, an electron gun deposition, a DC plating, a pulse plating, a physical vapor deposition, and a chemical vapor deposition. However, it is preferable to use the above-described method for preparing a preferred oriented Au film, that is, the pulse plating is preferably used for forming the first Au film and the second Au film having the preferably [111] oriented nanotwinned Au crystal lattice. In addition, the parameters for forming the above-mentioned first Au film and second Au film are regulated to obtain a thickness of 0.05-1000 μm, preferably 1-500 μm, and more preferably 1-10 μm, independently. In addition, the parameters for forming the above-mentioned first Au film and second Au film are regulated to provide a preferably [111] oriented crystal plane on the surface of the first Au film or the second Au film, wherein the first Au film surface has 50 to 100% by area of a [111] crystal plane, preferably 75 to 100%, and more preferably 85 to 100%. The crystallization morphology of the second Au film surface may not be limited, and can have 0-100% by area of the [111] crystal plane, preferably 50 to 100% by area of the [111] crystal plane, and more preferably 75 to 100% by area of the [111] crystal plane.

In the bonding process of the step (C), the pressing force is applied from the first substrate to the second substrate for lamination, or vice versa. Alternatively, the first substrate and the second substrate are pressed against each other for lamination. The pressing force may be 0.01 to 1000 MPa, and preferably 0.1 to 10 MPa. In addition, the bonding process may be performed at a vacuum of 10⁻⁴ to 10⁻² torr, and preferably 10⁻⁴ to 10⁻² torr. Furthermore, the bonding process of the step (C) may be performed at a temperature between 20° C. to 300° C. Furthermore, the time period for the bonding is not particularly limited, as long as the two substrates can be bonded via the Au film. Specifically, when the ambient temperature at the bonding process is relatively low, the time required for the bonding is relatively long. For example, when the bonding temperature is 150° C., the bonding time should be more than one hour. However, when the ambient temperature for the bonding is relatively high, the time required for the bonding is relatively short. For example, when the bonding temperature is 200° C., the required bonding time for completing the bonding process is merely 15 minutes.

In the bonding structure having the preferred oriented Au film and the preparation method thereof according to the present invention, the grain growth orientation is controlled to form the preferably [111] oriented crystal plane on the Au film surface, such that a thermos-compression bonding process is performed after the Au film surfaces are contacted. Upon bonding, the first Au film surface has more than 50% by area of the [111] crystal plane while the second Au film surface may have a randomly orientated crystal plane, or preferably have more than 50% by area of the [111] crystal plane. Since the [111] crystal plane is the closest packed plane of the face-centered cubic (FCC), it has a higher diffusion speed and a lower surface energy to facilitate seamless bonding. Therefore, as long as one of the bonding Au film surfaces has the preferably oriented [111] crystal plane, the faster diffusion rate of Au atoms in the [111] crystal plane would allow excellent bonding to be formed at low temperature and low pressure, thereby significantly reducing the production costs.

In addition, in the bonding structure having the preferably oriented Au film and the preparation method thereof according to the present invention, the first substrate and the second substrate may each independently be a semiconductor chip, a package substrate, or a circuit board; and preferably a semiconductor chip. Accordingly, the technique of the present invention can be applied to a variety of package techniques derived from IBM C4 technology, for example, flip-chip package, ball grid array (BGA), chip level chip scale packaging (WLCSP), and particularly suitable for the components with the high frequency and high power. In particular, the techniques of the present invention can be further applied to the three-dimensional package which requires higher mechanical properties and the product reliability. For example, when the first substrate and the second substrate are the semiconductor chips, they can be formed into the so-called three-dimensional integrated circuit (3D-IC) after bonding. In addition, the three-dimensional integrated circuit can be used as the first substrate while the package substrate is used as the second substrate for bonding. However, the present invention is not limited thereto.

### BRIEF DESCRIPTION OF THE DRAWINGS

FIG. 1 shows a schematic diagram of the crystal plane in the [111] orientation.

FIG. 2 shows the layout of the plating apparatus according to Preparation Examples 1 to 3 of the present invention.

FIG. 3A is a cross-sectional image of the nanotwinned Au film according to Preparation Example 1 of the present invention produced by focused ion beam.

FIG. 3B is a schematic three-dimensional view of the nanotwinned Au film according to Preparation Example 1 of the present invention.

FIG. 4 shows the analysis result of nanotwinned Au film according to Preparation Example 1 of the present invention by X-ray diffraction.

FIG. 5 shows the measurement result of the Au film surface formed in Preparation Example 2 by electron backscatter diffraction (EBSD).

FIGS. 6 and 7 show the thermos-compression bonding schemes according to Preparation Examples 2-3 of the present invention respectively.

FIG. 8 shows a cross-sectional SEM image of the Au film bonding structure according to Example 1 of the present invention.

FIG. 9 shows a cross-sectional SEM image of the Au film bonding structure according to Example 1 of the present invention.

FIG. 10 shows a cross-sectional view of the Au film bonding structure according to Example 1 of the present invention.

FIG. 11 shows a cross-sectional view of the Au film bonding structure according to Example 2 of the present invention.

FIG. 12 shows a cross-sectional view of the Au film bonding structure according to Example 3 of the present invention.

FIG. 13 shows the relationship between the indentation depth and the hardness of the Au film prepared in Preparation Example 1 of the present invention.

FIG. 14 shows the relationship between the indentation depth and the hardness of the Au film prepared in Preparation Example 3 of the present invention.

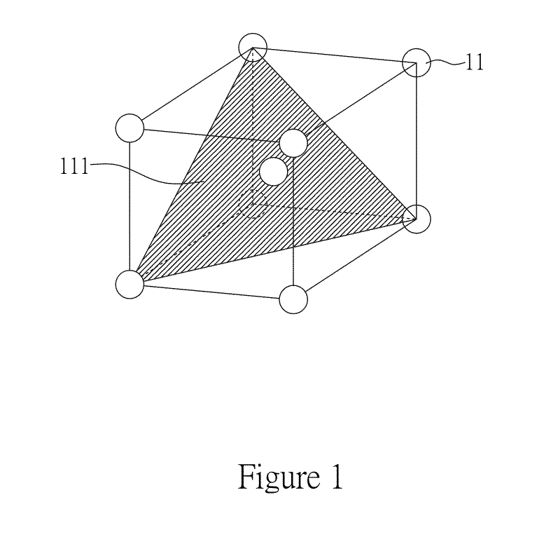

### DETAILED DESCRIPTION OF THE PREFERRED EMBODIMENT

Hereafter, examples will be provided to illustrate the embodiments of the present invention. Other advantages and effects of the invention will become more apparent from the disclosure of the present invention. Other various aspects also may be practiced or applied in the invention, and various modifications and variations can be made without departing from the spirit of the invention based on various concepts and applications.

### Preparation Example 1

### Preparation of Au Film Having Preferably [111] Oriented Nanotwinned Au Grains

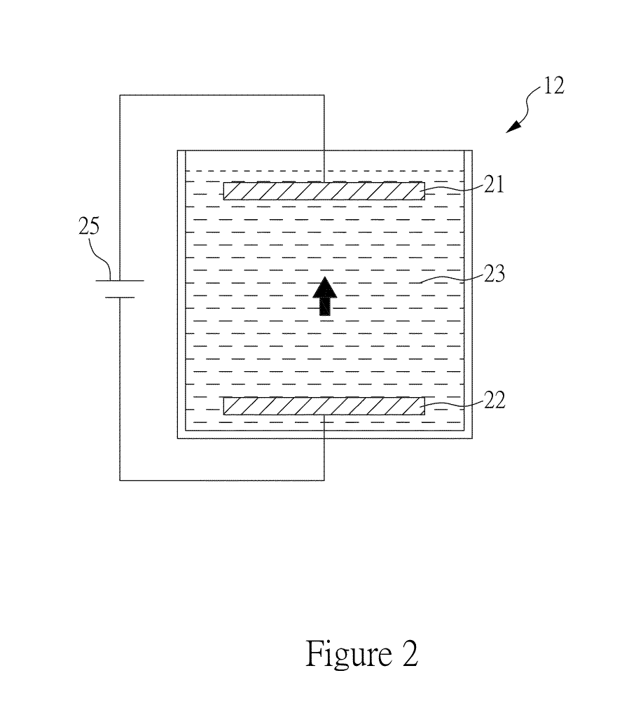

In this Preparation Example, an Au film having a preferred [111] oriented nanotwinned Au grains was prepared by plating. First, a plating apparatus 2 as shown in FIG. 2 was provided. The plating apparatus 2 included an anode 21, a cathode 22, which were immersed in the plating solution 3 and connected to a pulse current supply 25 (KEITHLEY2400) respectively. Here, the anode 21 was platinum substrate or grid; while the cathode 22 was a substrate coated with gold. However, a glass substrate, a quartz substrate, a metal substrate, a plastic substrate or a printed circuit board coated with a metal layer and a seed layer may also be chosen. The plating solution 23 comprised gold ions (10 g/L) prepared by dissociation of sulfite acid gold, hydrogen chloride (150 mL/L), nitrate (150 mL/L), and the secondary water (700 mL/L).

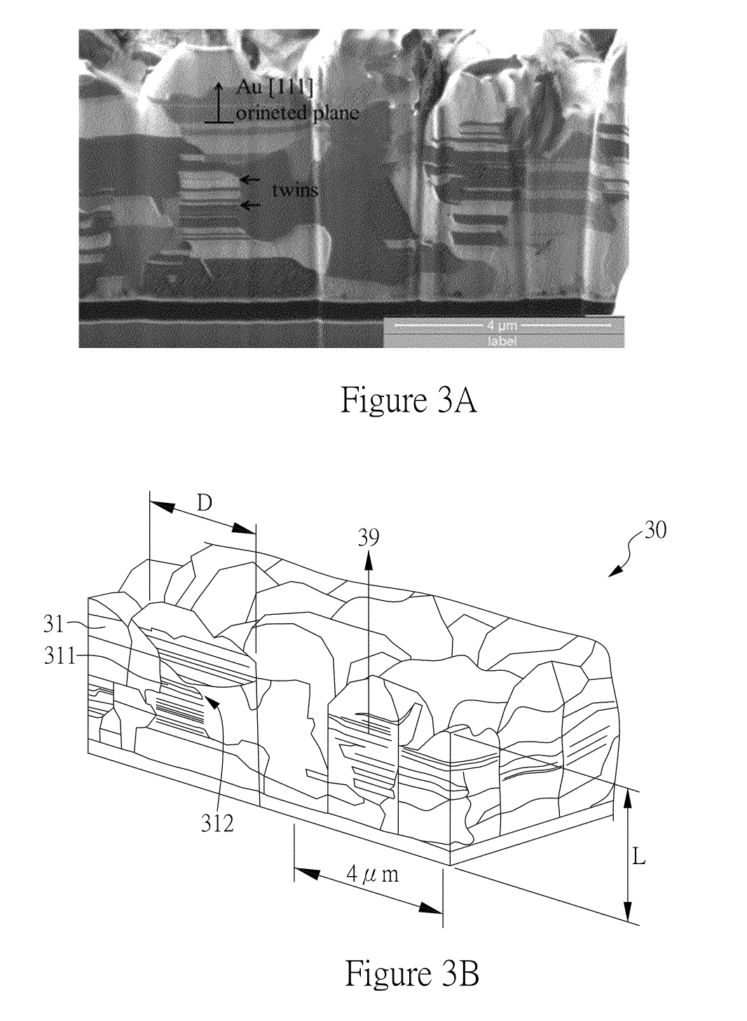

The, a pulse current with a current density of 0.005 A/cm² and Tₒₙ/T_{off} (sec) of 0.1s/1.4s was applied, and a magnet stirrer (not shown) was added therein to agitate the plating solution 23 at a rotational speed of 1200 rpm. Thus, an Au film including a plurality grains was grown from the cathode 22 toward the direction indicated by the arrow. FIG. 3A is a focused ion beam cross-sectional image of the nanotwinned Au film according to this Preparation Example of the present invention. FIG. 3B is a schematic three-dimensional view of the nano-twin Au film according to this Preparation Example of the present invention. As shown in FIGS. 3A and 3B, the grains 31 included a plurality of nano-twin Au grains 311 which were formed by stacking a plurality of nano-twin Au 312 along the [111] crystal axial orientation (e.g., the nano-twin Au composed of pairs of adjacent black lines and white lines were stacked along the direction 39 to constitute the nanotwinned Au grains 311). In the Au film 30 provided by this Preparation Example, the nanotwinned Au grains 311 had a thickness L of 1-10 μm and a diameter D of 0.5-5 μm.

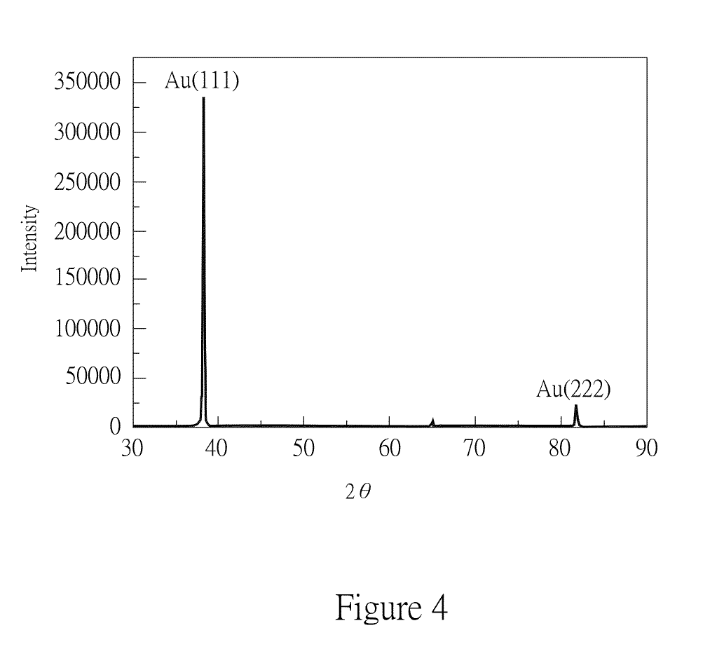

FIG. 4 shows the analysis result of nanotwinned Au film according to Preparation Example 1 of the present invention by X-ray diffraction. It can be seen from FIG. 4 that most of the Au grains had the preferred [111] crystal axial orientation (indicated by the “Au (111)” as labeled in FIG. 4).

### Preparation Example 2

### Preparation of Preferably [111] Oriented Au Film

In this Preparation Example, an Au film was prepared by plating. First, the same plating apparatus and the plating solution as in Preparation Example 1 were provided, as shown in FIG. 2. Then, at room temperature, a pulse current with a current density of 5 mA/cm² and Tₒₙ/T_{off} (sec) of 0.1s/1.0s was applied, and a rotating stirrer (not shown) was added to agitate the plating solution 23 at a rotational speed of 600 rpm. Thus, an Au film was grown from the cathode 22 toward the arrow-indicated direction.

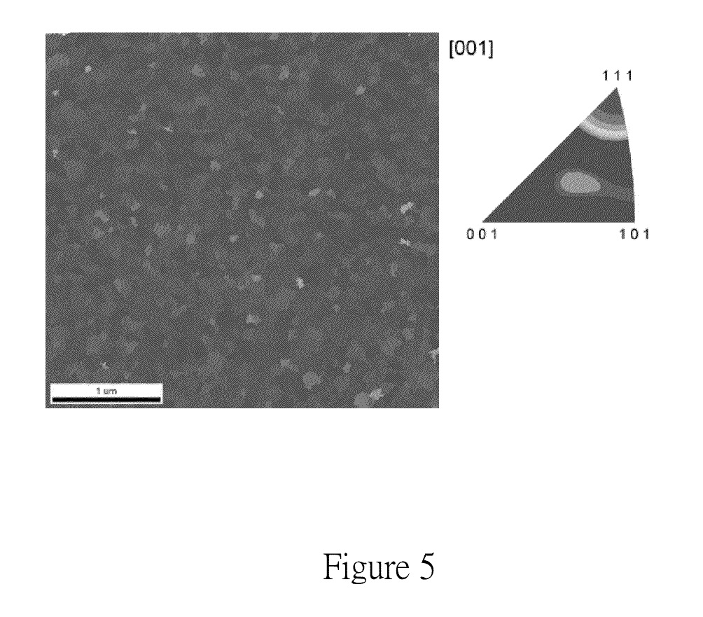

Then, the formed Au film surface was measured by electron backscatter diffraction (EBSD), and the results were shown in FIG. 5. The grain structure of the Au film surface can thus be observed to correctly determine the crystal orientation. After analysis, as shown in FIG. 5, the Au film surface prepared in this Preparation Example had more than 90% by area of the [111] crystal plane.

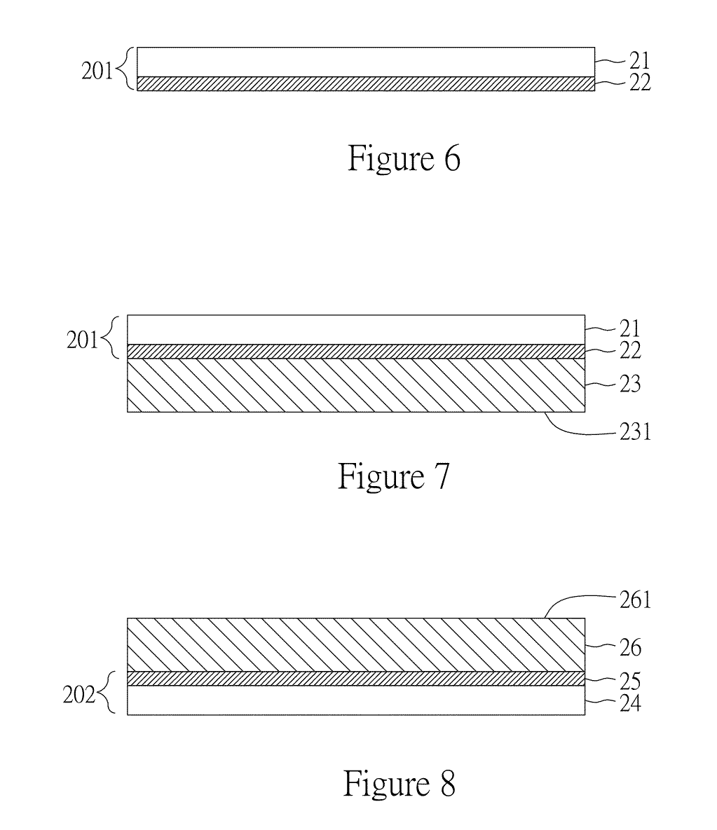

FIG. 6 shows the X -ray analysis results of the Au film prepared in this Preparation Example. It can be seen from FIG. 6 that most of the Au grains having the preferred [111] crystal axial orientation (indicated by the “Au (111)” as labeled in FIG. 6).

### Preparation Example 3

### Preparation of Irregularly Orientated Au Film

In this Preparation Example, an irregularly arranged Au film was prepared by plating. First, the same plating apparatus and the plating solution the same as in Preparation Example 1 were, as shown in FIG. 2. Then, the plating solution is heated to 60° C., and a pulse current with a current density of 5 mA/cm² and Tₒₙ/T_{off} (sec) of 0.1s/1.0s was applied, and a rotating stirrer (not shown) was added therein to agitate the plating solution 23 at a rotational speed of 600 rpm. Thus, an irregularly orientated Au film was grown from the cathode 22 toward the arrow-indicated direction.

FIG. 7 shows the X-ray analysis result of the Au film prepared in this Preparation Example. It can be seen from FIG. 7 that the grain arrangement of the Au film surface included a variety of orientations (indicated by “Au (111)”, “Au (200)”, “Au (220)”, “Au (400)”, “Au (311)” and “Au (222)” as labeled in FIG. 7).

### Example 1

### Bonding of Au Film

First, a first substrate and a second substrate were provided, and the plating method described in Preparation Example 1 was used to form a first Au film having the preferred [111] oriented nanotwinned Au grains on the first substrate. Then, on the second substrate, the plating method described in Preparation Example 3 was used to form the irregularly orientated second Au film. The first Au film had a thickness of about 5 μm while the second Au film had a thickness of about 7 μm. After this, as shown in FIG. 8, the first substrate 601 and the second substrate 602 were placed on the clamps 71, 72, respectively such that the first Au film surface 613 and the second Au film surface 661 faced towards each other, and then placed in a vacuum furnace at a low vacuum of 10⁻³ ton. The furnace was heated to 200° C. and maintained for 1 hour, and a pressing force of 0.78 MPa was applied. By the above steps, a bonding structure having the preferred oriented Au film was obtained.

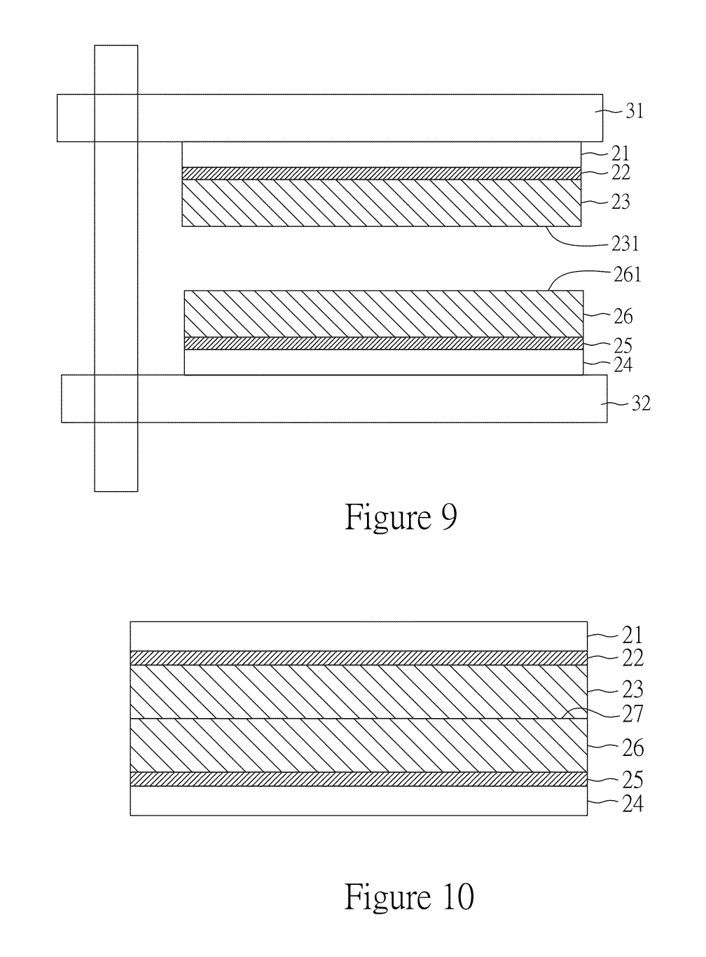

The completed Au film bonding structure was shown in FIG. 9, comprising: a first substrate 601 having a first Au film 63; and a second substrate 602 having a second Au film 66; wherein the first Au film 63 and the second Au film 63 were connected to each other and had an Au bonding interface 67.

FIG. 10 shows a cross-sectional view of the Au film bonding structure according to this Example, wherein the first Au film 61 had the preferred [111] oriented nanotwinned Au grains, and the second Au film 66 was an irregularly arranged Au film. This result shows that when the Au film with the nanotwinned Au grains was served as the bonding interface, no large void was produced at the bonding interface, indicating a good bonding quality.

### Example 2

### Bonding of Au Film

The method for bonding the Au film of this Example was substantially the same as in Example 1, except that the plating method described in Preparation Example 2 was used to form the preferred [111] oriented Au films on the first substrate and the second substrate respectively. In this Example, the first Au film surface and the second Au film surface had 50 to 100% by area of the [111] crystal plane and a thickness of 7 μm. By the bonding steps described in Example 1, a bonding structure having the preferred oriented Au film was obtained.

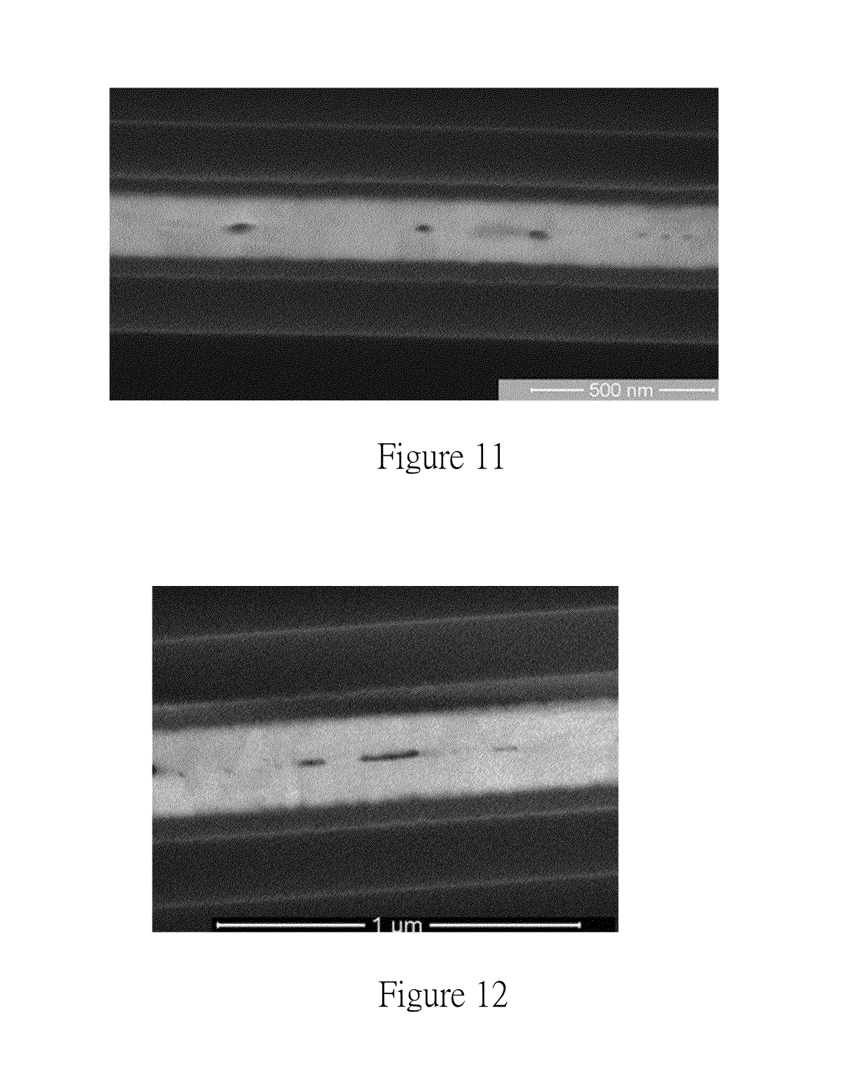

FIG. 11 shows a cross-sectional view of the Au film bonding structure completed by this Example, wherein the first Au film 61 and the second Au film 66 were both the preferred [111] oriented Au film. This result shows that when the [111] crystal plane was served as the bonding interface, no large void was produced at the bonding interface, indicating a good bonding quality.

### Example 3

### Bonding of Au Film

The method for bonding the Au film of this Example was substantially the same as in Example 1, except that the plating method described in Preparation Example 2 was used to form a preferred [111] oriented Au film on the first substrate, while the plating method described in Preparation Example 3 was used to form an irregularly orientated Au film on the second substrate. In this Example, the first Au film surface had 50 to 100% by area of the [111] crystal plane and a thickness of 7 μm. By the bonding steps described in Example 1, a bonding structure having the preferred oriented Au film was obtained.

FIG. 12 shows a cross-sectional view of the Au film bonding structure completed by this Example, wherein the first Au film 61 was a preferred [111] oriented Au film, and the second Au film 66 was an irregularly orientated Au film. This result shows that when the [111] crystal plane was served as the bonding interface, no large void was produced at the bonding interface, indicating a good bonding quality.

### Test Example 1

### Hardness Test

In this Test Example, hardness of the Au film having the preferred

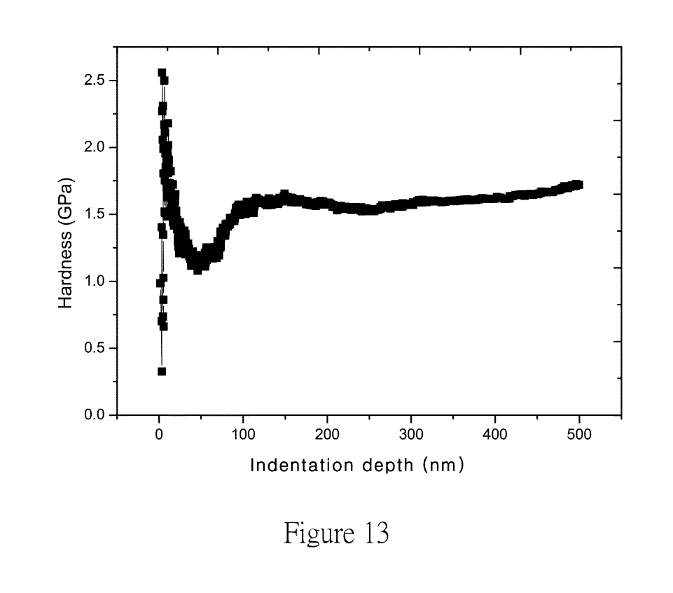

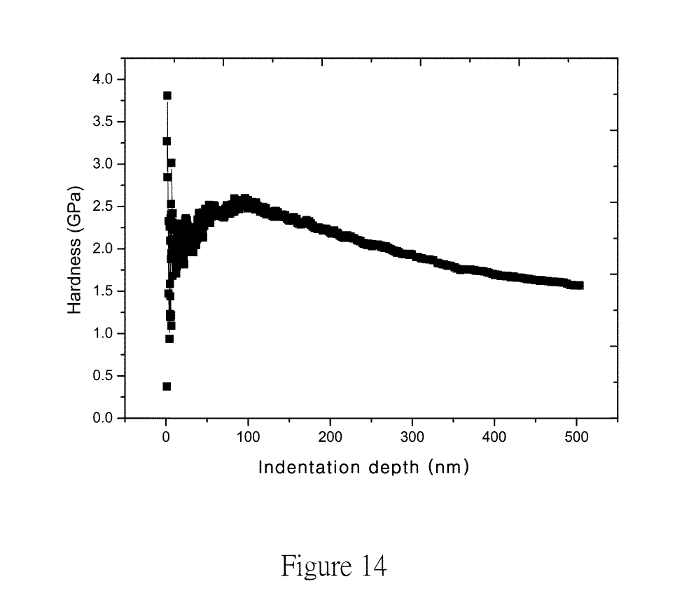

oriented nanotwinned Au grained prepared in the above Preparation Example 1 were measured by a nanoindenter at 9 indention points . The relationship between the indentation depth and the hardness is shown in FIG. 13, wherein the hardness was measured to be 1.646 GPa. Furthermore, the same method was used to measure the hardness of the irregularly orientated Au film prepared in Preparation Example 3, and the relationship between the indentation depth and the hardness is shown in FIG. 14, wherein the hardness was measured to be 1.2 GPa.

As apparent from the results of this Test Example, the hardness of the Au film having the preferred [111] oriented nanotwinned Au grains was improved by approximately 33% compared to the irregularly orientated Au film. Therefore, without affecting the gold ornament appearance, the hardness of the gold ornament can be increased. In addition, the preferred oriented Au film can also be served as an electrical contact of an electronic component, to improve the reliability and durability of the electrical contact.

The above embodiments are only for the purpose of better describing the present invention and are of exemplary nature, the scope of right asserted by the present invention is based on the scope of claims in this application, and are not intended to be limited by the above embodiments.

What is claimed is:

1. A preferred oriented Au film, comprising a plurality of Au grains connected to each other, wherein at least 50% by volume of the Au grains are composed of a plurality of nanotwinned Au grains, and the nanotwinned Au grains are formed of a plurality of nanotwinned Au stacked along a [111] crystal axial orientation.

2. The preferred oriented Au film of claim 1, wherein the Au film has a thickness direction, and any cross-section perpendicular to the thickness direction has at least 50% by area of a [111] crystal plane.

3. The preferred oriented Au film of claim 1, wherein the Au film has a thickness of 0.05-1000 μm.

4. The preferred oriented Au film of claim 1, wherein the nanotwinnedAu grains have a thickness of 0.05-1000 μm.

5. The preferred oriented Au film of claim 1, wherein the nanotwinnedAu grains have a diameter of 0.1-10 μm.

6. A method for preparing a preferred oriented Au film, comprising:
(A) providing a plating apparatus comprising an anode, a cathode, a pulsed current supply, and a plating solution, wherein the pulse current supply is electrically connected to the anode and the cathode which are immersed in the plating solution; and
(B) providing a pulse current for plating by using the pulsed current supply to grow an Au film on a surface of the cathode;
wherein the Au film comprises a plurality of Au grains connected to each other, wherein at least 50% by volume of the Au grains are composed of a plurality of nanotwinned Au grains, and the nanotwinned Au grains are formed of a plurality of nanotwinned Au stacked along a [111] crystal axial orientation; and the plating solution comprises a gold ion, a chloride ion, and an acid.

7. The method of claim 6, wherein in the step (B), the cathode or the plating solution is rotated at a rotational speed of 100-2000 rpm when plating.

8. The method of claim 6, wherein, in the step (B), the pulse current supply provides a pulse current having Tₒₙ/T_{off} (sec) of 0.1/0.4 to 0.1/2.

9. The method of claim 6, wherein in the step (B), the pulse current supply provides a pulse current having a current density of 1-100 mA/cm².

10. The method of claim 6, wherein the plating solution further comprises at least one selected from the group consisting of: a surfactant, a lattice modification agent, and mixtures thereof.

11. The method of claim 6, wherein the acid of the plating solution is at least one selected from the group consisting of: hydrochloric acid, nitric acid, and sulfuric acid.

12. The method of claim 6, wherein the acid of the plating solution has a concentration of 5-15 g/L.

13. The method of claim 6, wherein the gold ion of the plating solution is obtained by dissociation of a gold-containing salt which is at least one selected from the group consisting of: a sulfate and a sulfite.

14. The method of claim 6, wherein the chloride ion of the plating solution is at least one selected from the group consisting of: hydrochloric acid, perchloric acid, chloric acid, chlorous acid, and hypochlorous acid.

15. The method of claim 6, wherein the Au film has a thickness of 0.05-1000 μm.

16. The method of claim 6, wherein the nanotwinned Au grains have a thickness of 0.05-1000 μm.

17. The method of claim 6, wherein the nanotwinned Au grains have a diameter of 0.1-10 μm.

18. A bonding structure having a preferred oriented Au film, comprising:
a first substrate having a first Au film; and
a second substrate having a second Au film;
wherein the first Au film and the second Au film are connected to each other and have a bonding interface which has 50 to 100% by area of a crystal plane.

19. The bonding structure of claim 18, wherein each of the first Au film and the second Au film independently has a thickness of 0.05-1000 μm.

20. The bonding structure of claim 18, wherein each of the first substrate and the second substrate is independently selected from the group consisting of: a semiconductor chip, a circuit board, and a conductive substrate.

21. The bonding structure of claim 18, wherein a surface of the first Au film has 50 to 100% area of the [111] crystal plane; and a surface of the second Au film has 0 to 100% by area of the [111] crystal plane.

22. The bonding structure of claim 18, wherein each of the first Au film and the second Au film is independently formed by an electron gun deposition, a DC plating, a pulse plating, a physical vapor deposition, or a chemical vapor deposition.

23. The bonding structure of claim 18, wherein the first Au film and the second Au film comprise a plurality of Au grains connected to each other.

24. The bonding structure of claim 18, wherein at least one of the first Au film and the second Au film has at least more than 50% of the Au grains composed of a plurality of nanotwinned gold grains.
